(19) United States
(12) Patent Application Publication
(10) Pub. No.: US 2013/0065050 A1
(43) Pub. Date: Mar. 14, 2013

(54) PRODUCTION OF DECORATED CARBON NANOTUBES

(71) Applicants: Weixing Chen, Edmonton (CA); Xinwei Cui, Edmonton (CA)

(72) Inventors: Weixing Chen, Edmonton (CA); Xinwei Cui, Edmonton (CA)

(73) Assignee: The Governors of the University of Alberta, Edmonton (CA)

(21) Appl. No.: 13/698,951

(22) PCT Filed: May 19, 2011
(86) PCT No.: PCT/CA2011/050313

§ 371 Date: Nov. 19, 2012

Related U.S. Application Data
(60) Provisional application No. 61/346,361, filed on May 19, 2010.

(30) Foreign Application Priority Data
Aug. 12, 2010 (CA) 2712051

(51) Int. Cl. H01G 13/00; C23C 14/35; D01F 9/12; C25D 5/54; B82Y 30/00; B82Y 40/00

(52) U.S. Cl. 428/367; 427/79; 205/159; 204/192.17; 977/847; 977/742; 977/745; 977/846

(57) ABSTRACT

A method of dispersing a metal or metal oxide within a CNT or CNT array, comprising exposing the CNT or CNT array to a solution containing a metal compound in a non-aqueous liquid; and removing the non-aqueous liquid from the CNT or CNT array. Nanoparticles were homogenously deposited within millimeter-long carbon nanotube array (CNTA). After modified with nanoparticles, CNTA changes from hydrophobic to hydrophilic. The hydrophilic composite electrodes present ideal capacitive behavior with high reversibility. The novel, nano-architectured composite demonstrates strong promise for high-performance thick and compact electrochemical supercapacitors.

### CROSS-REFERENCE TO RELATED APPLICATIONS

This application claims the benefit under 35 USC 119(e) of U.S. provisional applications Ser. No. 61/346,361 filed May 19, 2010 and 61/373,174 filed Aug. 12, 2010, the contents of both of which are hereby incorporated by reference.

### TECHNICAL FIELD

Carbon nanotubes.

### BACKGROUND

Carbon nanotubes have many desirable properties making them useful or potentially useful for devices including electrochemical capacitors. Arrays of carbon nanotubes (CNTAs) are particularly useful. It is harder to make CNTAs of longer lengths than single nanotubes, and for the purpose of constructing electrodes, it is easier to use an array of nanotubes than a collection of separate nanotubes which would have to be bound together. However, arrays of carbon nanotubes are hydrophobic and in order to obtain best performance of CNTAs in an aqueous or similar electrolyte it is better for the arrays to be hydrophilic. Making a CNTA hydrophilic also enables deposition of further materials, for example by electrodeposition. The electrodeposition could be used to deposit many kinds of metals, alloys and oxide particles into the CNTA, including materials for which the method of deposition described below is inapplicable. Methods have been disclosed of depositing materials on random carbon nanotubes (CNTs) dispersed in solution or by mixing random CNTs with powders of chemicals, however these require the use of binding materials to construct an electrode.

Individual carbon nanotubes (CNTs) possess excellent electrical, thermal and mechanical properties; and a single CNT or dispersed CNTs have been widely used in the areas of field emission devices, electrochemical and biosensors, supercapacitors, etc. In the same manner, the mascroscopic forms of CNTs, e.g. millimeter-long carbon nanotube arrays (CNTAs), also have extraordinary properties, such as, high aspect ratio, aligned pore structure and high conductivity, chemical stability, etc. However, the applications of millimeter-long CNTAs are limited, primarily by the fabrication process, which can either damage the tubes or unable to control the configuration of the tubes within millimeter-long CNTAs. Recently, Hata et al. have developed a liquid-induced collapse method to prevent cracking of millimeter-long single-walled CNT arrays (SWCNTA) (S. Nat. Mater. 2006, 5, 987; Nano Lett. 2009, 9, 3302). Other limitations of using millimeter-long CNTAs are their hydrophobic nature and dense packing of CNTs, which restricts the insertion of aqueous electrolyte into the inner porous CNTAs and the usage of the whole surface area of CNTAs, including the decoration of CNTAs by methods such as direct electroposition in aqueous electrolytes and sputtering.

Due to the extraordinary properties of CNTAs, millimeter-long CNTAs have been attempted to be used as supercapacitors in aqueous and organic electrolytes . Specifically, Zhang et al. reported a capacitance of 14.1 F/g for 0.8 mm long CNTA in 7 M KOH electrolyte, and around 22 F/g for 1.0 mm long CNTA in an ionic liquid electrolyte. Thus, utilization of the electrical double-layer capacitance (EDLCs) of CNTA couldn't give high-performance electrochemical supercapacitors (ESs). In order to increase energy density as well as power density, transitional metal oxides must be deposited within CNTAs to form Faradic pseudo-capacitors. In addition, it is advantageous to use millimetre-long CNTAs as the catalyst support for pseudo-capacitors, because the energy density and power density of supercapacitor cells can be increased by occupying high ratios of cell's weight with active material. This thick and compact electrode should possess high capacitance, as well as be operable at high rate, and may be useful for applications with area-limited configuration (e.g. micromechanical systems (MEMS), on chip devices, etc.). Transitional metal oxides such as manganese oxides have been coated on activated mesocarbon microbead, mesoporous carbon, dispersed CNTs, etc. However, due to the limitations of millimeter-long CNTAs mentioned above, up to now, no method has been reported to fabricate millimeter-long CNTA with transition metal oxides well dispersed in it, except that Zhang et al. has reported a potentiodynamic electrodeposition method that was able to deposit ˜100 nm diameter manganese oxide nanoflowers within within CNTAs in an aqueous electrolyte; however, their method is only applicable to the decoration of short CNTAs (<35 μm).

Alternative methods to form oxides on CNTs could be electroplating, sputtering, atomic layer deposition, chemical vapor deposition, etc, but these methods are not suitable to form oxides on CNTAs due to the close positioning and hydrophobicity of CNTs in CNTAs.

### SUMMARY

In one embodiment there is disclosed a method of making an array of carbon nanotubes hydrophilic, the array of carbon nanotubes being hydrophobic when initially grown. The array is made hydrophilic by the deposition of a metal or metal oxide within the array. It is not strictly necessary that the metal or metal oxide be a transition metal or transition metal oxide. In order to deposit the metal or metal oxide in a hydrophobic CNTA, the CNTA is exposed to a solution of a non-aqueous liquid containing a compound which is deposited in the CNTA. The exposure may comprise immersing, dipping or dripping. The compound may be a compound other than an oxide, the compound comprising a metal. The compound may have higher solubility in the non-aqueous liquid than the metal or an oxide of the metal. After the exposure to the solution, the CNTA may be dried. The CNTA is then annealed. If the compound is not an oxide, in the annealing step the compound may be broken down to form an oxide. If a reduction environment is used, the compound may be broken down to form a metal.

In another embodiment, there is disclosed a method of dispersing a metal or metal oxide within a CNT, comprising physically contacting a metal or metal oxide precursor with a CNT; and annealing the CNT and metal or metal oxide precursor to cause a metal or metal oxide to bind chemically with carbon atoms of the CNT.

In an embodiment, Mn₃O₄ nanoparticles or other oxide nanoparticles are uniformly dispersed within carbon nanotube array (CNTA) to form oxide/CNTA composite arrays through dip-casting method. After modified with oxide nanoparticles, CNTA changes from hydrophobic to hydrophilic. The hydrophilic oxide/CNTA composite electrode presents high capacitance, long cycle life, making it very promising for ESs.

In another embodiment, there is disclosed a method of depositing a metal, alloy or oxide in a CNT or CNT array, comprising the steps of: modifying the CNT or CNT array to make it hydrophilic by dispersing a metal or metal oxide within it according to the method of any one of claims 1-13; and depositing a metal, alloy or oxide in the modified CNT or CNT array by electrodeposition.

In another embodiment, there is disclosed a method of dispersing a metal or metal oxide within a CNT or CNT array, comprising the steps of: exposing the CNT or CNT array to a solution containing a metal compound in a non-aqueous liquid; and removing the non-aqueous liquid from the CNT or CNT array.

In another embodiment, there is disclosed a CNT or CNT array comprising a metal or metal oxide dispersed within the CNT or CNT array.

In another embodiment, there is disclosed a capacitor comprising the CNT or CNT array of any one of the methods disclosed herein.

In another embodiment, there is disclosed a method of dispersing a metal, metal compound, or metal oxide within a CNT or CNT array, comprising the steps of: exposing the CNT or CNT array to a solution containing a metal compound in a non-aqueous liquid; and removing the non-aqueous liquid from the CNT or CNT array.

The disclosed methods may be used to produce well-dispersed nanoparticles within a CNTA. The nanoparticles can be of small size and the CNTA can be of any length, not just a millimeter-long CNTA. The CNTA can be on a non-conducting substrate. The CNTA can be rolled or pressed and the above method can be applied before, during or after the rolling or pressing. The method may also be applied to random CNTs.

Embodiments of the disclosed methods are applicable to metals or oxides of metals for which one of the salts of that metal can be dissolved within non-aqueous solution (e.g. ethanol). Basically, the organic liquids, such as ethanol, acetone, ethylene glycol, etc., can be used to produce alternate oxides on the CNT surface. Metal oxides for which the above method can be applied include LiOx, MgOx, CaOx, TiOx, CrOx, MnOx, FeOx, CoOx, NiOx, CuOx, VOx, ZnOx, ZrOx, NbOx, TaOx, MoOx, RuOx, AgOx, SnOx, SbOx, CeOx, LaOx, PdOx, YOx, Tin-doped Indium oxide, and InOx. Metals for which the above method can be applied include Li, Mg, Ca, Cr, Mn, Fe, Co, Zn, Ni, Cu, Ni/Cu alloy, V, Zr, Nb, Ta, Ti, Mo, Ru, In, Sn, Sb, Ag, Au or Pd. CNTs or CNT arrays made by the disclosed methods are also provided, including CNTs or CNT arrays comprising a metal or metal oxide dispersed within the CNT or CNT array.

In various embodiments, there may be included any one or more of the following features: Exposing comprises dipping the CNT or CNT array into a solution containing a metal compound in a non-aqueous liquid. Removing the non-aqueous liquid from the CNT or CNT array comprises drying the CNT or CNT array. The methods further the CNT or CNT array. In the annealing step, a metal oxide is formed dispersed within the CNT or CNT array. The metal oxide comprises one or more of LiOx, MgOx, CaOx, TiOx, CrOx, MnOx, FeOx, CoOx, NiOx, CuOx, VOx, ZnOx, ZrOx, NbOx, TaOx, MoOx, RuOx, AgOx, SnOx, SbOx, CeOx, LaOx, PdOx, YOx, Tin-doped Indium oxide, or InOx. In the annealing step, a metal is formed dispersed within the CNT or CNT array. A reduction environment is used in the annealing step. The metal comprises one or more of Li, Mg, Ca, Cr, Mn, Fe, Co, Zn, Ni, Cu, Ni/Cu alloy, V, Zr, Nb, Ta, Ti, Mo, Ru, In, Sn, Sb, Ag, Au or Pd. Exposing comprises dripping the solution containing a metal compound onto the CNT or CNT array after dipping the CNT or CNT array into the solution containing a metal compound. The metal compound comprises Mn(CH₃COO)₂. The CNT or CNT array is produced by CCVD. The non-aqueous solution comprises ethanol. The metal or metal oxide is dispersed within the CNT or CNT array by dip-casting. A CNT or CNT array within which a metal, alloy or oxide has been deposited according to any of the methods disclosed herein. The CNT or CNT array is a millimeter-long CNT or CNT array. The CNT is a random CNT and physically contacting a metal or metal oxide precursor with a CNT comprises at least one of electroplating, sputtering, chemical vapor deposition, atomic layer deposition and physical vapor deposition. The CNT is part of a CNTA array and physically contacting a metal or metal oxide precursor with a CNT comprises: exposing the CNTA to a solution containing a metal compound in a non-aqueous liquid; and removing the non-aqueous liquid from the CNTA. Exposing comprises dipping the CNTA into a solution containing a metal compound in a non-aqueous liquid. Removing the non-aqueous liquid from the CNTA comprises drying the CNTA. Any of the methods further comprising annealing the CNT or CNTA. In the annealing step, a metal oxide is formed dispersed within the CNTA. Any of the methods applied to a CNT or CNT array. In the annealing step, a metal compound is formed dispersed within the CNT or CNT array. The metal compound formed dispersed within the CNT or CNT array comprises one or more of LiOH, MgSO₄, CaCO₃, NiCO₃, or LaO₂CO₃.

These and other aspects of the product and method are set out in the claims, which are incorporated here by reference.

### BRIEF DESCRIPTION OF THE FIGURES

Embodiments will now be described with reference to the figures, in which like reference characters denote like elements, by way of example, and in which:

FIG. 1 is a composite image showing elements of FIGS. 2, 6 and 7, including a schematic drawing and close-up image of a Mn₃O₄/CNTA composite electrode;

FIG. 2 is a schematic diagram of making Mn₃O₄/CNTA composite electrode. The insert image is the photograph of the composite electrode before it is sealed with green Mask-it;

FIG. 3 is a surface morphology and (c,d) cross section FESM images of Mn₃O₄/CNTA composites at different magnifications. (e) Cross-section SEM image of Mn₃O₄/CNTA composite and its corresponding EDS mapping patterns for C, Mn and O;

FIG. 4 is (a) Bright-field and (b) dark-field TEM images of Mn₃O₄/CNTA(0.33). (c) Bright-field and (d) dark-field TEM images of Mn₃O₄/CNTA(0.84)

FIG. 5 shows surface wettability of as-grown CNTA with a contact angle of 138 degrees;

FIG. 6 is (a) time sequence images of a water droplet dropped to the surface of Mn₃O₄/CNTA composite and (b) Schematic diagram of the inner structure of Mn₃O₄/CNTA composite showing how the composite works in ESs;

FIG. 7 is (a) TEM image of Mn₃O₄/CNTA(0.33) and its inset HRTEM image of the Mn₃O₄ nanoparticle. (b) EDS and (c) SAD patterns detected from Mn₃O₄/CNTA(0.33) in (a). (d) Statistical distribution of Mn₃O₄ nanoparticle size deposited within CNTA in Mn₃O₄/CNTA(0.33). (e) TEM image of Mn₃O₄/CNTA(0.84). (f) Statistical districution of Mn₃O₄ nanoparticle size deposited within CNTA in Mn₃O₄/CNTA(0.84);

FIG. 8 is an XPS MN 3s spectrum from Mn₃O₄/CNTA composite. The splitting width of the doublet peaks is indicated;

FIG. 9 is CV curves of (a) Mn₃O₄/CNTA(0.84) composite electrode and (b) Mn₃O₄/CNTA(0.84) composite electrode detected in 0.5 M Na₂SO₄ electrolyte at various scan rates spanning from 2 mV/s to 200 mV/s. (c) Specific capacitance for Mn₃O₄/CNTA composite electrodes at two different loadings and as-grown CNTA electrode calculated from galvanostatic charge-discharge curves at various current densities. (d) Nyquist plot for the as grown CNTA electrode;

FIG. 10 is (a) CV curves of Mn₃O₄/CNTA composite electrodes at two different loadings and as-grown CNTA electrode at 50 mV/s. (b) Galvanostatic charge-discharge curves of the three electrodes at 1 A/g. (c) Specific capacitance for the three electrodes calculated from CV curves at various scan rates. (d) Specific capacitance for the deposited Mn₃O₄ nanoparticles for the composite electrodes with two loadings at various scan rates; and

FIG. 11 is (a) Nyquist plots for Mn₃O₄/CNTA(0.84) and Mn₃O₄/CNTA(0.33) composite electrodes. (b) Variation of capacitance with respect to CV cycle number for Mn₃O₄/CNTA(0.84) and Mn₃O₄/CNTA(0.33) composite electrodes and also for the deposit Mn₃O₄ nanoparticles.

### DETAILED DESCRIPTION

In the disclosed dip-casting method, an oxide precursor, such as manganese acetate, in a carrier liquid, such as ethanol, is brought into contact with a CNT array and then the carrier is removed to leave the oxide precursor physically in contact with the CNTs in the CNT array Annealing of the CNTs causes the oxide precursor to bind chemically with the CNTs to form metal oxide particles chemically bonded (dispersed) within the CNT array. In the case of random CNTs, other methods may be used to form CNTs decorated with oxides that are chemically bonded to the CNTs by first bringing the metal oxide precursor into physical contact with the CNTs and then annealing the CNTs to cause a chemical bonding of the metal oxide to the carbon atoms of the CNTS. Methods for bringing the oxide precursor into contact with the random CNTs include electroplating, sputtering, chemical vapor deposition, atomic layer deposition and physical vapor deposition Annealing may be effected by heating the oxide precursor to a temperate and for a time sufficient to cause chemical bonding of the oxide to carbon atoms of the CNT, without destroying the CNT. If the metal oxide precursor does not already provide oxygen for bonding, the process may be carried out in the presence of free oxygen. Using the dip-casting method, the CNT array would maintain its vertically aligned structure after functionalized with oxide particles. After being functionalized with oxide particles using our method, the CNT array would change from hydrophobic to hydrophilic, because of the uniformly deposition of oxide particles along CNTs within the CNT array. After conversion of the CNT array from hydrophobic to hydrophilic, other deposition methods, such as electroplating, can be used to further deposit other elements into the CNT array without destroying its vertically aligned structure. When used with arrays, the disclosed methods do not require purification of CNTs as the normal case for random CNTs or well dispersion of CNTs before deposition.

We disclose a process for depositing a material on carbon nanotubes (CNTs). The process can be applied to CNTs in carbon nanotube arrays (CNTAs) which previous methods have not been able to easily coat, however, it can also be applied to purified random CNTs. The CNTs can be either single walled or multi-walled and of any length. The CNT materials should be placed on a substrate that allows liquid draining and drying. The CNTs are soaked in a solution of a metal oxide or metal precursor compound in an organic liquid. The organic liquid may include, for example, ethanol, acetone, or ethylene glycol. The soaking can occur by dip-casting or by dripping. In a first embodiment, a CNTA is dipped in manganese (II) acetate [Mn(CH₃COO)₂.4(H₂O)]—ethanol solution and followed by dropping the CNTA with the same solution for 10 minutes. In a second embodiment, manganese (III) acetate [C₆H₉MnO₆.2(H₂O)]—ethanol solution is dripped onto a CNTA. Further embodiments using different solutions to produce different metal oxides or metals are shown below. The soaked CNTAs or CNTs are dried in air for at least 1 hour. The CNTAs or CNTs may be further dried in a furnace. The dried CNTAs or CNTs are then annealed, for example at 300° C. for 2 hrs. The annealing helps to form nano-oxide particles uniformly on the surface of the CNTs. The annealing may be adjusted depending on the choice of metal or oxide. The annealing may also be performed in a controlled environment to prevent decomposition of CNT structures and if desired to assist in the reaction between oxides and carbon atoms of CNTs.

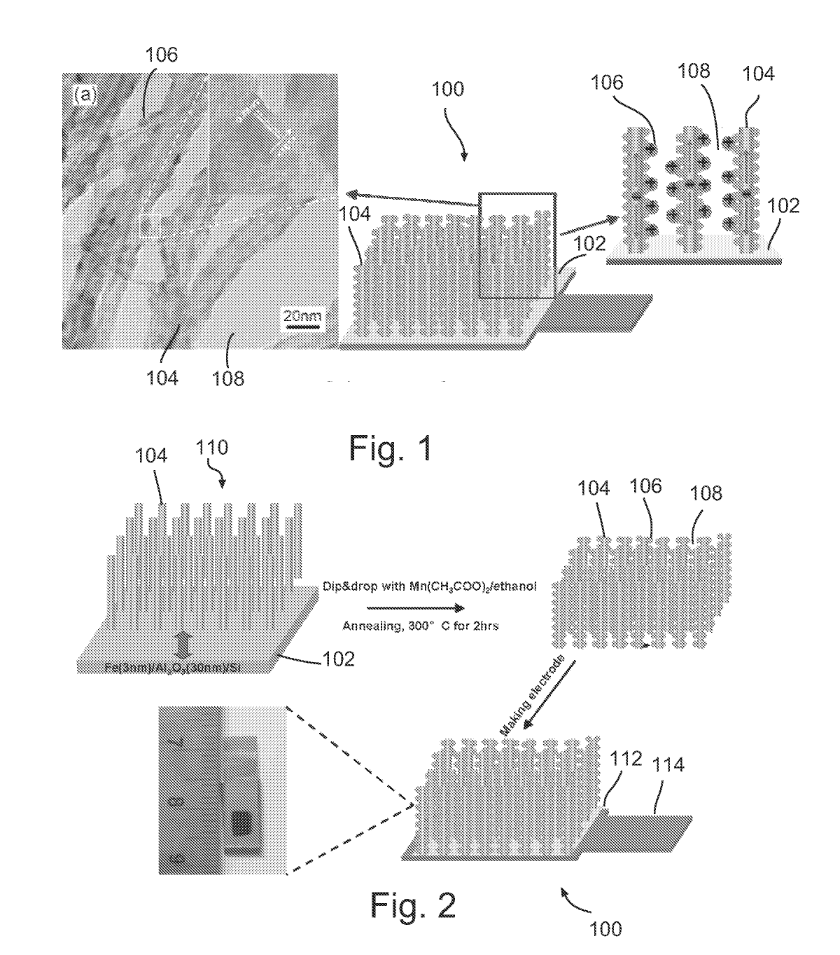

We have successfully achieved the goal of depositing metal oxides in CNTAs by dip-casting Mn₃O₄ nanoparticles uniformly dispersed within 0.9 mm long CNTA scaffold. Two different Mn₃O₄ nanoparticle loadings (mass ratio of Mn₃O₄/CNTA) were used to prepare the composite arrays, a high Mn₃O₄ loading (84%) and a low Mn₃O₄ loading (33%). The corresponding composites will be denoted as Mn₃O₄/CNTA(0.84) and Mn₃O₄/CNTA(0.33), respectively. The contact angle measurement shows that the as prepared Mn₃O₄/CNTA composites are hydrophilic, which is an important factor for the improved performance of ESs. The maximum specific capacitance of the Mn₃O₄/CNTA(0.84) composite electrode was found to be 143 F/g, leading to a high area-normalized capacitance of 1.70 F/cm2, while the specific capacitance for the as-grown CNTA electrode is only 1-2 F/g. When normalized to the mass of the deposited Mn₃O₄ nanoparticles, the specific capacitance was estimated to be as high as 292 F/g. A high-rate capacity was also shown for the Mn₃O₄ in the composite electrodes, 100 F/g in Mn₃O₄/CNTA(0.84) and 181 F/g in Mn₃O₄/CNTA(0.33) at a scan rate of 100 mV/s. This work not only develops a novel Mn₃O₄/CNTA composite which is promising for high performance thick and compact ESs, and but also opens up a new route of utilizing ultra-long CNTAs. FIG. 1 shows a Mn₃O₄/CNTA composite electrode generally indicated by reference numeral 100. The composite electrode includes CNTs 104 coated by Mn₃O₄ nanoparticles 106. The CNTs extend from substrate 102. In between the CNTs are channels 108 rendered hydrophilic by the presence of the nanoparticles. FIG. 1 shows a schematic drawing in the centre, with a close-up image of coated CNTs at the left, with a further magnified inset; and a close up schematic drawing on the right.

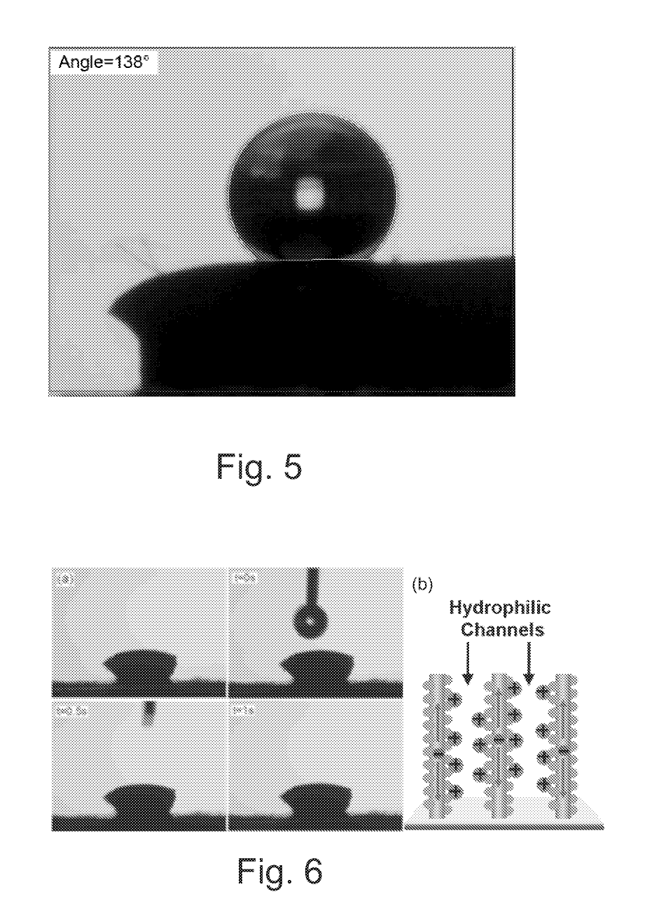

The approach we used to form the Mn₃O₄/CNTA composite is schematically illustrated in FIG. 2. The composite electrodes preparation briefly includes the following steps: (1) Growth of millimeter-long CNTA 110. The individual CNTs within the as-grown CNTAs were determined to have an average diameter of 11.5 nm with CNT wall number of 5-7/ The height and density of the CNTAs is 0.9 mm and 0.069 g/cm³, respectively. Based on these data, it was calculated that 92.3% empty space exists in our as-grown CNTAs. Detailed characterization of the as-grown CNTAs was presented in detail in Cui, X; Wei, W; Harrower, C; Chen W. Carbon 2009, 47, 3441. The density of our as-grown CNTA is two times larger than that (0.03 g/cm3) for 1 mm long SWCNTA. It should be the large differences in wall number and CNTA inner diameter that induce this deviation of CNTA density. (2) Since the as-grown CNTA is hydrophobic with a contact angle of 138° (as shown in FIG. 5), a non-aqueous solvent is used to wet The CNTA. The CNTA could be well wetted by some non-aqueous liquids, including ethanol, acetone, ethylene glycol, etc. In this step, we dipped the as-grown CNTAs in Mn(CH₃COO)₂ ethanol solution. The CNTAs' good wettability to the ethanol solution makes the dissolved Mn(CH₃COO)₂ able to penetrate into the highly packed, aligned CNTs (CNTA matrix) together with the ethanol liquid. (3) Subsequent annealing at 300° C. for 2 h in air converts the absorbed Mn(II) cations into dispersive Mn₃O₄ nanocrystals on the CNTA framework to form Mn₃O₄ composites. (4) Electrodes were then made by sputtering a layer 112 of Au to the bottom of the composites and attaching the sputtered side to the conductive tape 114. Our strategy to form the Mn₃O₄/CNTA composite electrodes is schematically illustrated in FIG. 2. It is worthy to note that this strategy can also be extended to integrate other metal oxide nanoparticles, or even metallic nanoparticles (by annealing in reducing environments), into CNTA for different applications. Other non-aqueous solvents are also applicable, such as acetone, ethylene glycol, etc.

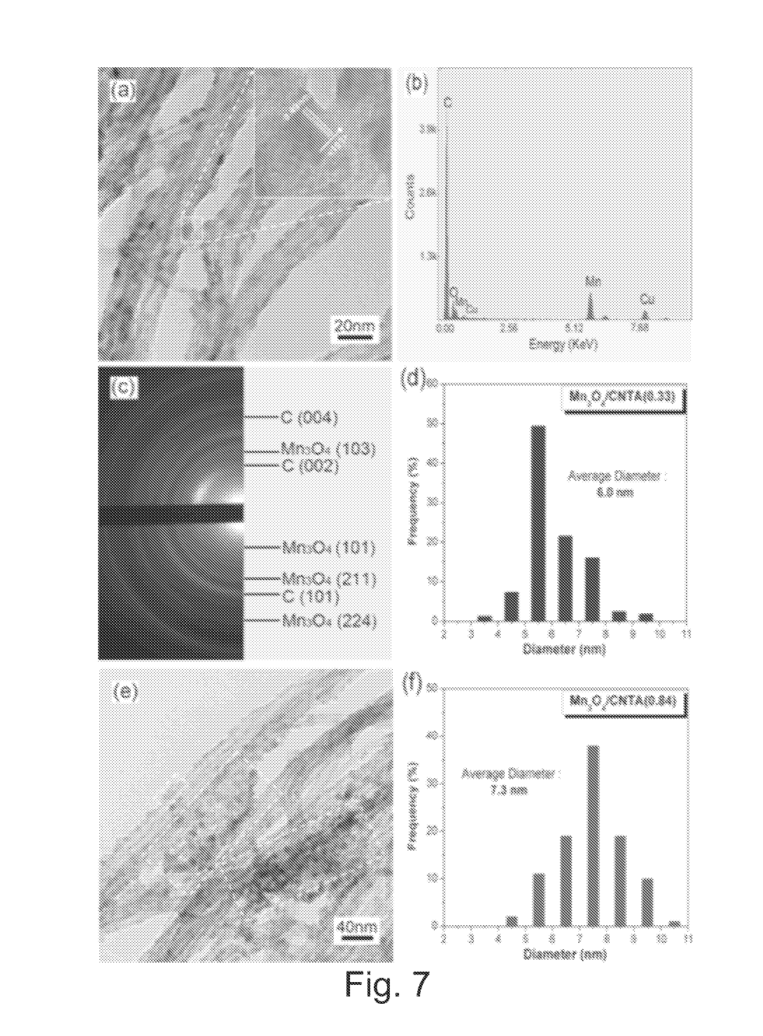

The morphology, chemistry and crystal structure of the composites were investigated by transmission electron microscopy (TEM) and energy-dispersive spectroscopy (EDS) shown in FIG. 7. FIG. 7a is a TEM image of a strip of Mn₃O₄/CNTA(0.33) taken from the centre of the composite. It is clearly displayed that, after the dip-casting treatment, the CNT walls appear serrated with decorated nanoparticles. These nanoparticles are well dispersed along the CNTs. EDS result shown in FIG. 7b gives the chemistry in the region in FIG. 7a. Only C, O, Mn and Cu (from Cu grid) peaks are detected suggesting that the composite is very clean and the decorated particles are manganese oxides. In order to obtain the crystal structure of the manganese oxide nanoparticles, the selected area diffraction (SAD) was conducted and the SAD pattern is shown in FIG. 7c. It is determined that, in addition to well known CNT diffraction rings (graphitic carbon), allother diffraction rings can be assigned to tetragonal hausmannite-Mn₃O₄ phase [space group I41/amd with lattice constants a=b=5.762 Å and c=9.470 Å (JCPDS 24-0734)], with the strong rings for Mn₃O₄ (101), (103) and (211) planes. The high resolution TEM (HRTEM) image in the inset of FIG. 7a also confirms the crystal structure presented in FIG. 7c. Therefore, TEM investigation reveals that the inserted Mn(CH₃COO)₂ salts have been transferred to nanocrystalline Mn₃O₄ particles within millimeter-long CNTA during the annealing at 300° C. for 2 hrs in air. A TEM micrograph of a strip of Mn₃O₄/CNTA(0.84) composite is also shown in FIG. 7e. The high Mn₃O₄ loading in the composite exhibits similar structure as that for the low Mn₃O₄ loading in FIG. 7a, except that nanoparticle aggregation occured in Mn₃O₄/CNTA(0.84) as indicated in the frames in FIG. 7e. The nanoparticle aggregation was also supported in FIG. 4 by comparing the bright-field and dark-field TEM images of the two composites. Furthermore, the statistical distributions of the Mn₃O₄ nanoparticle size in the two composites were acquired from the bright-field TEM images taken from 10 different locations. Mn₃O₄ nanoparticle size distributes in a very narrow range with an average size of 6.0 nm for Mn₃O₄/CNTA(0.33) and 7.3 nm for Mn₃O₄/CNTA(0.84), as shown in FIGS. 7d and 7f, respectively.

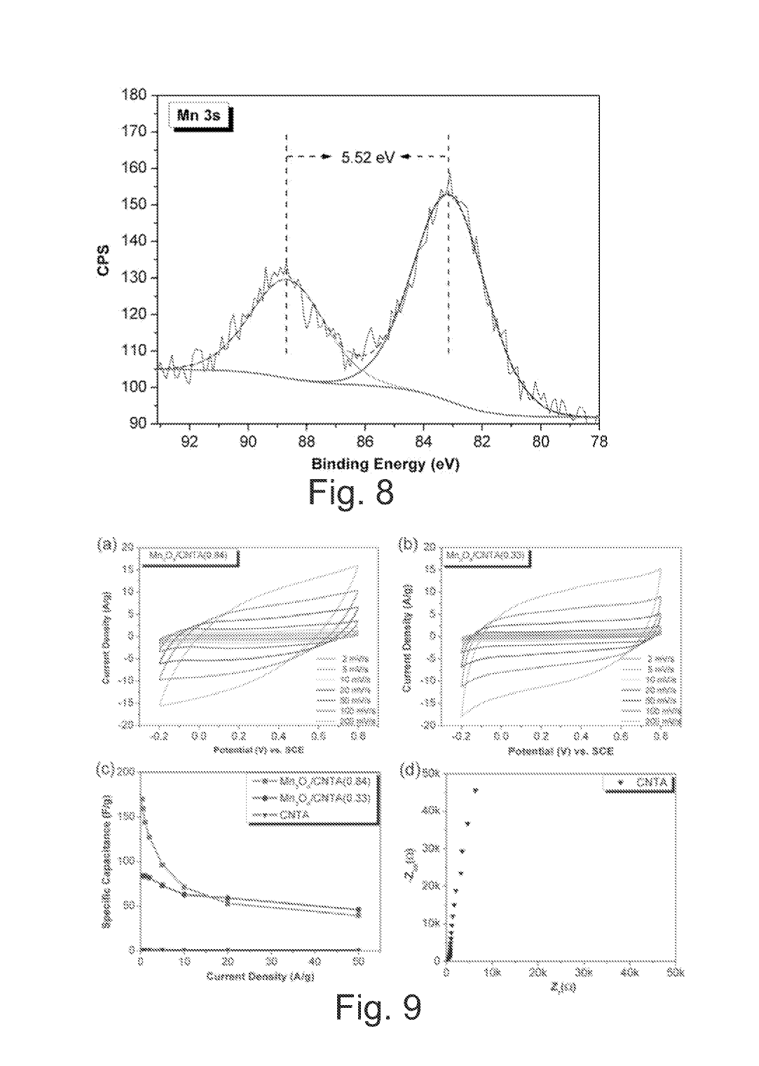

X-ray photoelectron spectroscopy (XPS) was also employed to study the chemical state of the deposited manganese oxide nanoparticles by analyzing the high resolution Mn 3s doublet peaks. The doublet Mn 3s peaks are caused by the parallel spin coupling between electrons in the 3s and 3d orbitals. The oxidation states of Mn increases with the decrease of 3s peak splitting widths (EA) in an approximately linear relation. As shown in FIG. 8, AEis 5.52 eV, which can be converted into an average oxidation valence of +2.5, suggesting that the manganese oxides are in the form of Mn₃O₄. This is consistent with the crystal structure obtained from SAD pattern in FIG. 7c.

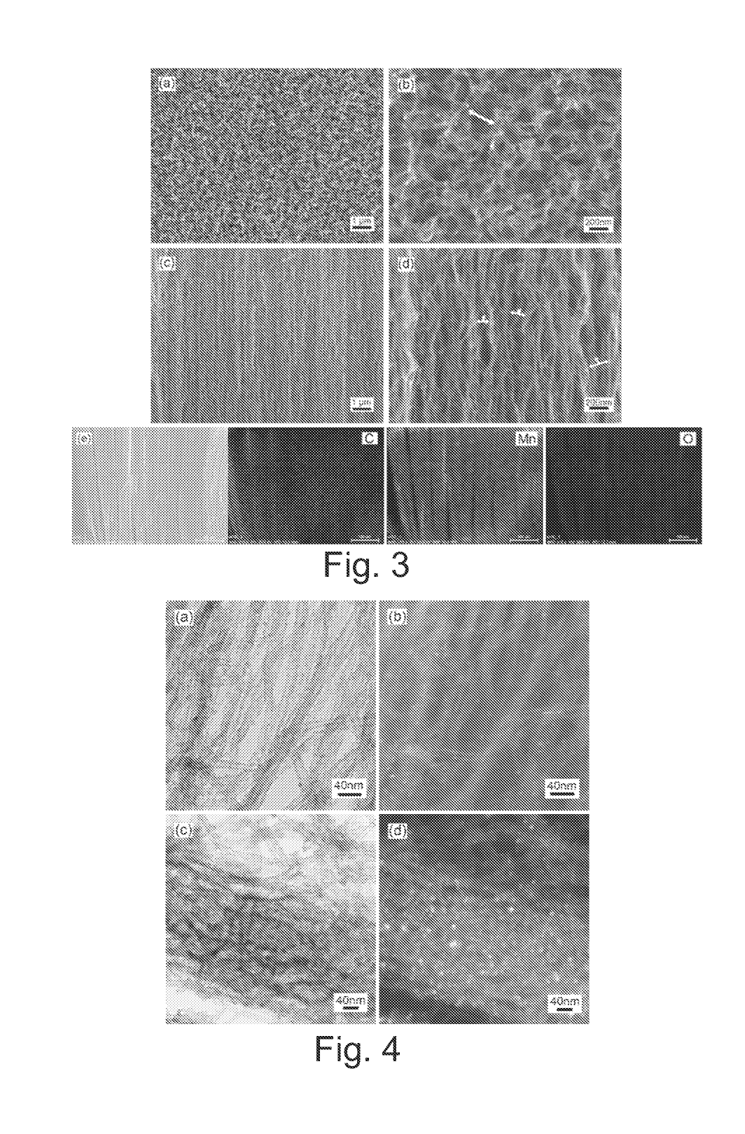

FIG. 3 shows the surface morphology and cross section field-emission scanning electron microscopy (FESEM) micrographs of the composites after annealing at 300° C. for 2 hrs. It is noted that the volume of the CNTA was reduced by 7% after dipping the ethanol solution and annealing at 300° C. This zipping effect is believed to be caused by the change of surface tension of the liquids during evaporation, which is consistent with the observation reported before. The reason of little decrease of CNTA volume after annealing can be seen from FIG. 3. The composite did not zip to near-ideal graphitic spacing as the case for 1 mm long SWCNTA, but retained the original morphology of CNTA with aligned macropores or macrochannels indicated by the arrows in FIGS. 3b and 3d. These aligned macrochannels are advantageous in terms of the performance of ESs, which will be discussed later. Additionally, the uniformity of Mn₃O₄ nanoparticle distribution within the large range of the composites was confirmed by EDS mapping shown in FIG. 3e. Therefore, the obtained structures were composite arrays with Mn₃O₄ nanoparticles homogeneously distributed within highly dense, millimeter-long CNTAs. The dip casting method can be applied to integrate other metal oxide nanoparticles, ormetallic nanoparticles (by annealing in reducing environments), into highly dense CNTAs. Combining with its own extraordinary properties, CNTA is an ideal support for active material. Direct deposition of nanoparticles within CNTAs also saves several procedures that are needed for the deposition of nanoparticles on dispersed CNTs, such as CNT purification, filtering, mixture with binding material, etc. It may also stimulate the future efforts on the fabrication of patterned 3D composite arrays.

Many applications involving the use of dispersed CNTs and CNTA strongly depend on their surface wettability. Up to now, the most developed method used to change CNT wettability is surface functionalization. However, the surface functionalization is only applicable to the dispersed or entangled CNTs, as CNTA could be easily fractured and/or collapse during solution evaporation after surface functionalization. Tuning surface wettability during the process of CNTA growth is another solution, but the tuning range is very limited. Interestingly, we have found that the Mn₃O₄ nanoparticle decorated CNTA is completely hydrophilic, as shown in FIG. 6a. The standing time of the small water droplet on the surface of the composite is less than 0.5 s. Although a fair amount of Mn was introduced into the CNTA, it provides another route to change the wettability of CNTA without destroying their alignment and integrity. More importantly, this surprising change of wettability to aqueous electrolytes for millimeter-long CNTAs, not only broadens their applications, for example in ESs, but also allows CNTAs to be treated by other methods in aqueous solutions, for instance electrodeposition method.

The very short standing time for the water droplet on the surface of the array indicates that the water droplet completely inserted into the aligned hydrophilic pore or channels (typically indicated by the arrows in FIGS. 3b and 3d) within the array. Dubal et al. reported that Mn₃O₄ thin film is hydrophilic with a contact angle of 60°. Thus, the hydrophilicity of the composite array should be ascribed to the Mn₃O₄ nanoparticles well dispersed and decorated on CNT walls. The gap between those decorated CNTs forms the aligned hydrophilic channels. Hence, the aligned hydrophilic channels for electrolyte ion transportation, the Mn₃O₄ nanoparticles for Faradaic reactions and the good conductivity of CNTA (schematically shown in FIG. 6b), imply that the novel composite array is very promising for high performance area-limited electrode ESs, which will be discussed in the following section.

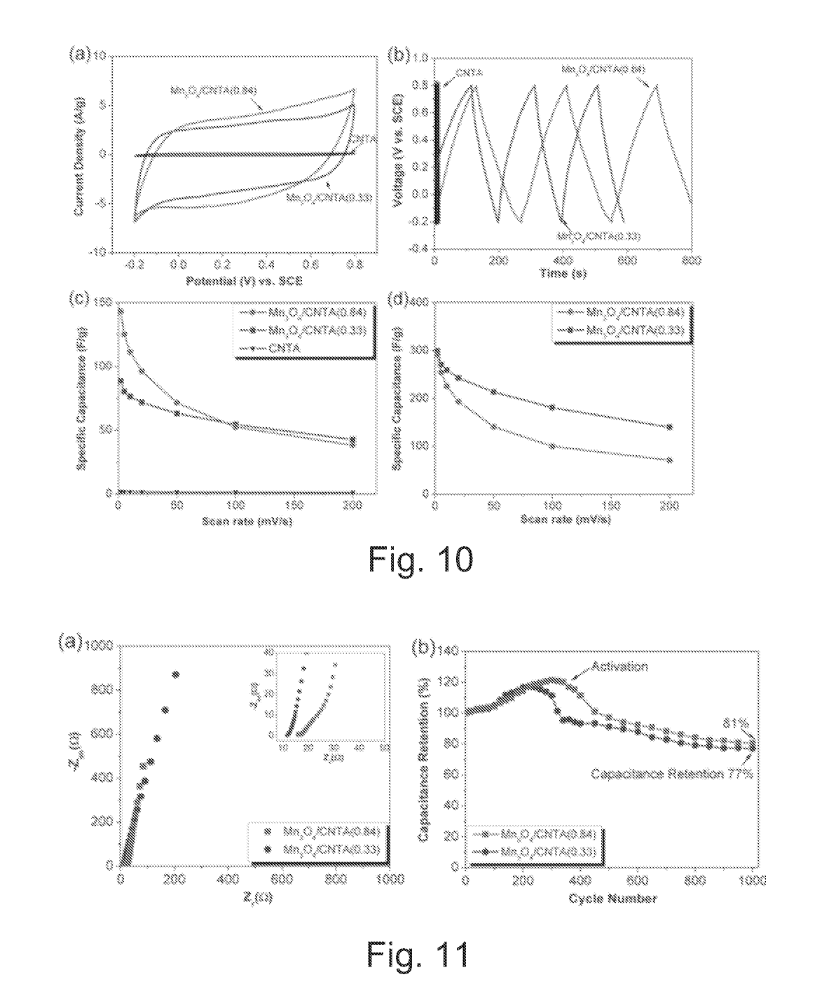

Electrochemical properties of the Mn₃O₄/CNTA(0.84) and Mn₃O₄/CNTA(0.33) composite electrodes are shown in FIGS. 9, 10, and 11. The cyclic voltammetry (CV) curves of the two composite electrodes in 0.5 M Na2SO4 electrolyte at various scan rates are shown in FIGS. 9a and 9b. For comparison, the CV curves at a scan rate of 50 mV/s for the two composite electrodes and as-grown CNTA electrode are displayed in FIG. 10a; and galvanostatic charge-discharge curves at the specific current of 1 A/g for these three electrodes are displayed in FIG. 10b. FIG. 10a shows that the shape of CV curves are nearly rectangular with no obvious redox peaks from −0.2 and 0.8V (vs. SCE), which indicates good capacitive performance for these three electrodes. This is also confirmed by the closely linear galvanostatic charge-discharging curves at a specific current of 1 A/g in FIG. 10b. In addition, as shown in FIG. 10b a negligible voltage (IR) drop was detected for the composite electrodes, suggesting their low internal resistance. The specific capacitance of these three electrodes was also plotted versus various scan rates and specific currents in FIGS. 10c and 9c, respectively. The comparable values measured by these two methods reflect that the specific capacitance obtained in this study is of high accuracy. The highest specific capacitance of 143 F/g was given by the Mn₃O₄/CNTA(0.84) composite electrode at a scan rate 2 mV/s. This value is almost one order of magnitude higher than the results reported in the literature for different heights of CNTA detected in aqueous and organic solutions; and even higher than the activated, thin film and dispersed CNTs. The specific capacitance, therefore, should be primarily contributed from the pseudo-capacitance of the deposited Mn₃O₄ nanoparticles. This is consistent with the huge difference of CV curves and charge-discharge curves between the composite electrodes and the as-grown CNTA electrode, shown in FIGS. 10a and 10b. Interestingly, when projecting the electrode structure in three dimensions with a limited footprint, the area-normalized capacitance (Faraday per geometric area of the electrode) for the Mn₃O₄/CNTA(0.84) and Mn₃O₄/CNTA(0.33) composite electrodes is 1.70 F/cm2 and 0.79 F/cm2, respectively. This is one order higher than that for Mn₃O₄ thin films and much higher than that for MnO₂—carbon composite (usually around 0.01-0.05 F/cm²). The high area-normalized capacitance of 1.70 F/cm² should be ascribed to the high loading of Mn₃O₄ nanoparticles in the Mn₃O₄/CNTA(0.84), which was determined to be 5.46 mg/cm². The importance of employing the high loading of Mn₃O₄ nanoparticles is that the relative mass of other components of supercapacitor cells becomes less significant; and thus the energy and power densities per gram of the cells increase. Therefore, these results imply that newly developed Mn₃O₄/CNTA composite electrode is an improved area-limited electrode for ESs. The capacitance values for these three electrodes derived from cyclic voltammetry were summarized in Table I. It should also be noted that, in this investigation, the specific capacitance of the as-grown CNTA electrode is in the range of 1-2 F/g, an order of magnitude lower than those reported in the literature. One reason for the above discrepancy is that the CNTA used in this study is very thick, 0.9 mm, and CNTA is hydrophobic with a contact of angle of 138° (FIG. 5); thus, the actual surface used for EDLC may be only within the outmost 100 μm. Another important reason is related to the neural aqueous electrolyte used, 0.5 M Na₂SO₄ with pH around 7. In the literature, the electrochemical performance of CNTA and CNTs were mostly determined in acidic H₂SO₄ or alkaline KOH electrolytes, which may activate the CNTA or CNTs for increased performance during the cycling process.

Since the aqueous electrolyte was proved to be capable of penetrating into the Mn₃O₄/CNTA composite arrays, more surface of CNTA should be exposed to the electrolyte. To accurately determine the specific pseudo-capacitance of the deposited Mn₃O₄, the specific capacitance of the as-grown CNTA under different scan rates obtained in this study was magnified 10 times to the comparative values in the literature. They were then subtracted from the total specific capacitance of the composite electrodes by considering the mass ratios of Mn₃O₄:CNTA. The calculated specific pseudo-capacitance contributed purely from the deposited Mn₃O₄ nanoparticles was presented in FIG. 10d. It is noted that the maximum specific capacitance for the two different Mn₃O₄-loading electrodes has comparable values, 292 F/g for Mn₃O₄/CNTA(0.84) and 299 F/g for Mn₃O₄/CNTA(0.33), which justifies the method used to acquire the specific capacitance for the Mn₃O₄. It also rationalizes the high energy density for the Mn₃O₄ nanoparticles. Recently, Dai et al. reported a specific capacitance of 131.2 F/g and Dubal et al. reported a specific capacitance of 193 F/g for Mn₃O₄ films. Most other results in the literature are lower than these two values, because it is known that Mn₃O₄ is a low-specific capacitance material compared with MnO₂. However, in this study, FIG. 10d and FIG. 7 indicate that Mn₃O₄ could also have a high specific capacitance by decreasing the Mn₃O₄ particle size to less than 10 nm in diameter (FIGS. 7d and 7f), since this allows full access of the active material, Mn₃O₄, to the aqueous electrolyte. Furthermore, at a high scan rate of 100 mV/s, the specific capacitance of the Mn₃O₄ still maintains as high as 100 F/g in Mn₃O₄/CNTA(0.84) and 181 F/g in Mn₃O₄/CNTA(0.33), indicating high rate capacity and high power density of the Mn₃O₄. This property should also be attributed to the aligned hydrophilic channels and nanosized Mn₃O₄ particles even at high loadings. The aligned hydrophilic channels provide fast electrolyte ion diffusion into the composite array, and nanosized Mn₃O₄ particles offer short cation diffusion path for bulk Faradaic reactions. These results prove that the electrochemical performance of transitional metal oxides, both in terms of capacitance and power characteristics, strongly depends on their electrode structure. We have also discussed the importance of Mn oxides morphology, crystal structure, cation valences and defect chemistry to the specific capacitance in Wei, W.; Chen, W; Ivey, D. G. J. Phys Chem C 2007, 111, 10398, Wei, W.; Cui X.; Chen, W.; Ivey, D. G. J. Phys. Chem C 2008, 112, 15075 and Wei, W.; Cui X.; Chen, W.; Ivey, D. G. Electrochim. Acta 2009, 54, 2271. The specific surface area of the deposited Mn₃O₄ nanoparticles for Mn₃O₄/CNTA(0.84) was calculated to be 169 m²/g. The calculation was made based on the TEM characterization of Mn₃O₄ nanoparticle size (FIG. 7f) and the assumption that Mn₃O₄ nanoparticle has the same mass density as its bulk material. Hence, the capacitance per cm² of surface area of the deposited Mn₃O₄ was determined to be 186 μF/cm², which is more than one order of magnitude higher than that of EDLCs for pure carbon materials (5-20 μF/cm²).

FIG. 11a shows the Nyquist plots for the two composite electrodes analyzed by electrochemical impedance spectroscopy (EIS). It reveals that the charge-transfer resistance for Mn₃O₄/CNTA(0.84) is ˜12Ω, which is much larger than that for Mn₃O₄/CNTA(0.33), ˜1.2Ω. Such high charge-transfer resistance for Mn₃O₄/CNTA(0.84) would be detrimental to its rate capacity, which is consistent with the CV results shown in FIGS. 10c and 10d where Mn₃O₄/CNTA(0.84) has inferior capacitance at high scan rates comparing with Mn₃O₄/CNTA(0.33). This trend can be attributed to the larger Mn₃O₄ size and nanoparticle aggregation for Mn₃O₄/CNTA(0.84) observed in TEM images in FIG. 7e, 7f and FIG. 4. In both cases, the cation diffusion path in the active material increases resulting in the decrease of rate capacity. FIG. 11b shows the capacitance retention of the composite arrays versus cycle number. A slight increase of specific capacitance around 200-300 cycles suggests an activation process occurred in the initial stage of cycling, which may be due to the oxidation of Mn₃O₄ to MnO₂. The specific capacitance retains 77%-81% of the original value after 1000 cycles at a scan rate of 50 mV/s.

Although the electrochemical performance of supercapacitors has been significantly improved by incorporation of Mn₃O₄ nanoparticles within highly dense, millimeter-long CNTAs, further optimization of this hierarchical porous structures is achievable through methods such as tuning the height of electrodes, manipulating the size of hydrophilic channels, using different transitional metal oxides by dip-casting method or even electrodeposition after dip-casting.

We have homogeneously deposited Mn₃O₄ nanoparticles within highly dense, millimeter-long carbon nanotube array (CNTA) through dip-casting method from non-aqueous solutions. After modified with Mn₃O₄ nanoparticles, CNTAs have been changed from hydrophobic to hydrophilic without their alignment and integrity being destroyed. The hydrophilic Mn₃O₄/CNTA composite electrode presents high capacitance, long cycle life, making it very promising for ESs. Interestingly, the deposited Mn₃O₄ nanoparticles demonstrate superior specific capacitance and rate capacity because of their nanosize and the excellent nanostructured scaffold, millimeter-long CNTA. In addition to supercapacitors, this 3D-nanoparticle decorated hierarchical porous structure is also desired for many other applications, such as hydrogen storage, gas or liquid sensors, lithium ion batteries, etc. Therefore, this work not only develops a novel, nano-architectured Mn₃O₄/CNTA composite which is promising for high performance area-limited ESs, but, more importantly, provides a new route of decorating highly dense CNTAs with active materials.

The experimental procedure used for producing and characterizing the CNTA/Mn₃O₄ composite is described in more detail below.

Catalytic chemical vapor deposition (CCVD) was used to grow millimeter-long CNTAs. P-type Si wafers (100) coated with a buffer layer of 30 nm Al₂O₃ film and a catalyst film of 3 nm Fe by DC magnetron sputtering were used as the substrates. Catalyst film pretreatment and MWCNT array growth for CCVD were conducted in a single-zone quartz tube furnace with an inner diameter of 5 in. The tube chamber was first evacuated to ≦0.1 Torr. After Ar purging for 1 h, the furnace temperature was ramped up to 750˜800° C. and held for 60 min under 200 sccm Ar and 400 sccm H₂ gas flow. 400 sccm C₂H₄ was then flowed into the system for 30 min. At the end of CNTA growth, the flow of H₂ and C₂H₄ was terminated and the system was purged again with Ar during furnace cooling to below 100° C. After the CCVD process, we obtained 0.9 mm long CNTA growing on the non-conductive substrate.

The Mn₃O₄/CNTA composite electrode was prepared as follows and schematically shown in FIG. 2. (1) The as-grown CNTA was removed from the non-conductive substrate and completely immersed into Mn(CH₃COO)₂.4H₂O/ethanol solution for 3 min. (2) The dipped CNTA was quickly taken out and dripped by the same solution for 10 drops, 1 drop (˜0.014 ml) each minute. (3) The dripped CNTA was dried at room temperature and atmosphere for 2 hrs, and put into 100° C. furnace for 1 hr. (4) Then, the sample was annealed at 300° C. for 2 hrs to form Mn₃O₄/CNTA composite. (5) A thin Au layer was sputtered to the back of the dip-casted composite, which was then attached to a double-sided conducting tape and sealed the exposed area (other than the composite electrode) with a green Mask-it (purchased from Caswell, Inc.). The final geometric surface area of the composites is in the range of 15 mm² to 25 mm². The weight of the as-grown CNTA and the composite were measured by the microbalance of Accu-225D (Fisher Scientific) with a weighing precision of 10 μg. The mass loading of the Mn₃O₄ was calculated from their weight difference. The solvent used is denatured alcohol with 85% ethanol and 15% methanol. 0.25 M Mn(CH₃COO)₂.4H₂O/ethanol solution was used to prepare Mn₃O₄/CNTA(0.84) composite array, while 0.1 M Mn(CH₃COO)₂.4H₂O/ethanol solution was used to prepare Mn₃O₄/CNTA(0.33) composite array. For comparison, as-grown CNTAs were also fabricated to the pure CNTA electrodes by removing the as-grown CNTA from the substrate and only conducting step (5).

The nanostructure and chemistry of as-grown CNTA and Mn₃O₄/CNTA composite were characterized by JSM-6301FXV (JOEL) field emission scanning electron microscopy (FESEM) and JAMP 9500F (JOEL) field emission scanning Auger microprobe (FE-SAM), and also by transmission electron microscopy (TEM) (JOEL 2010 equipped with a Noran ultra-thin window (UTW) X-ray detector). Chemical state analysis was carried out by X-ray photoelectron spectroscopy (XPS) using a Kratos AXIS Ultra-x-ray photoelectron spectrometer. A monochromatic Al source, operating at 210 W with a pass energy of 20 eV and a step of 0.1 eV, was utilized. Curve fitting and background subtraction were accomplished using Casa XPS Version 2.3.13 software. Energy-dispersive spectroscopy (EDS) mapping was acquired by a peltier-cooled 10 mm² Bruker Quantax Silicon drift detector attached to Zeiss EVO MA 15 LaB₆ filament SEM. The contact angle measurement device used was FTA200 (First Ten Angstroms).

Electrochemical capacitive behavior was investigated with a Solartron SI1287 potentiostat/galvanostat under cyclic voltammetry (CV) and galvanostatic charge-discharge modes, and with a Gamry PC4/750 potentiostat/galvanostat under potentiostatic electrochemical impedance spectroscopy (EIS) mode, in the aqueous electrolyte of 0.5 M Na₂SO₄. A three-electrode cell configuration was employed, consisting of the pure CNTA or composite electrode as the working electrode, a platinum plate as the counter electrode and a saturated calomel electrode (SCE) as the reference electrode. All potentials quoted are with respect to SCE. Cyclic voltammograms were recorded between −0.2 and 0.8V (vs. SCE) at various scan rates ranging from 2 mV/s to 200 mV/s. The galvanostatic charge-discharge was also conducted in the voltage range of −0.2 and 0.8V (vs. SCE) at various specific currents spanning from 0.5 A/g to 75 A/g. EIS measurements were conducted in constant voltage mode (0.4V vs. SCE) by sweeping frequencies from 100 kHz to 0.01 Hz at an amplitude of 5 mV.

The above method is applicable to metals or oxides of metals for which one of the salts of that metal can be dissolved within non-aqueous solution (e.g. ethanol). Basically, the organic liquids, such as ethanol, acetone, ethylene glycol, etc., can be used to produce alternate oxides on the CNT surface. Metal oxides for which the above method can be applied include LiOx, MgOx, CaOx, TiOx, CrOx, MnOx, FeOx, CoOx, NiOx, CuOx, VOx, ZnOx, ZrOx, NbOx, TaOx, MoOx, RuOx, AgOx, SnOx, SbOx, CeOx, LaOx, PdOx, YOx, Tin-doped Indium oxide, or InOx. Metals for which the above method can be applied include Li, Mg, Ca, Cr, Mn, Fe, Co, Zn, Ni, Cu, Ni/Cu alloy, V, Zr, Nb, Ta, Ti, Mo, Ru, In, Sn, Sb, Ag, Au or Pd. Further disclosure of the use of different metals and metal oxides in the above method is shown below.

LiOH, Li, Li₂O
1) Dissolve LiOH in ethanol, and dip the solution into the CNTAs. This structure can be used as a CO₂ capture.
2) Dissolve LiCH₃COO in ethanol and dip the solution into the CNTAs. When heated to 70 to 700° C., LiCH₃COO would decompose to form Li metal or Li₂O, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

MgO, Mg
1) Dissolve Mg(CH₃COO)₂ in ethanol, and dip the solution into the CNTAs. When heated to 80 to 700° C., Mg(CH₃COO)₂ would decompose to form MgO and Mg, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))
2) MgSO₄ would also work.

CaCO₃, CaO, Ca
1) Dissolve Ca(CH₃COO)₂ in methanol, and dip the solution into the CNTAs. When heated to 160 to 700° C., Ca(CH3COO)₂ would decompose to form CaCO₃, CaO and Ca, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

TiO₂, TiO, Ti₂O₃, Ti
1) Dissolve titanium isopropoxide or titanium ethoxide in ethanol, and dip the solution into the CNTAs. When heated to 100 to 700° C., titanium isopropoxide or titanium ethoxide would decompose to form TiO₂, TiO, Ti₂O₃ and Ti, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

CrO₂, Cr₂O₃, CrO, Cr
1) Dissolve chromium dimethylamino ethoxides in ethanol, and dip the solution into the CNTAs. When heated to 100 to 700° C., chromium dimethylamino ethoxides would decompose to form CrO₂, Cr₂O₃, CrO and Cr, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

MnO, Mn₂O₃, Mn₃O₄, Mn
1) Dissolve Mn(CH₃COO)₂ in ethanol, and dip the solution into the CNTAs. When heated to 150 to 700° C., Mn(CH₃COO)₂ would decompose to form MnO, Mn₂O₃, Mn₃O₄ and Mn, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

FeO, α-Fe₂O₃, γ-Fe₂O₃, Fe₃O₄, Fe
1) Dissolve Fe(CH₃COO)₂ or Fe(CH₃COO)₃ in ethanol, and dip the solution into the CNTAs. When heated to 140 to 700° C., Fe(CH₃COO)₂ or Fe(CH₃COO)₃ would decompose to form FeO, α-Fe₂O₃, γ-Fe₂O₃, Fe₃O₄ and Fe, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

COO, Co₂O₃, Co₃O₄, Co
1) Dissolve Co(CH₃COO)₂ in ethanol, and dip the solution into the CNTAs. When heated to 140 to 700° C., Co(CH₃COO)₂ would decompose to form CoO, Co₂O₃, Co₃O₄ and Co, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

NiCO₃, NiO, Ni
1) Dissolve Ni(CH₃COO)₂ in ethanol, and dip the solution into the CNTAs. When heated to 200 to 700° C., Ni(CH₃COO)₂ would decompose to form NiCO₃, NiO and Ni, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

Cu₂O, CuO, Cu
1) Dissolve Cu(CH₃COO)₂ in ethanol, and dip the solution into the CNTAs. When heated to 115 to 700° C., Cu(CH₃COO)₂ would decompose to form Cu₂O, CuO and Cu, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

VO₂, V₂O₅, V₂O₃, VO, V
1) Dissolve vanadium alkoxide molecular precursors in ethanol, and dip the solution into the CNTAs. When heated to 200 to 700° C., the precursors would decompose to form VO₂, V₂O₅, V₂O₃, VO, and V, depending on the heating temperature and environment (inert gases (e.g., N₂, Ar), reducing gases (e.g., H₂, Ar/H₂, N₂/H₂, CO) and oxidation gases (e.g., air, O₂, Ar/O₂, N₂/O₂))

ZnO, Zn
1) Dissolve Zn(CH₃COO)₂ in ethanol, and dip the solution into the CNTAs. When heated to 237 to 700° C., Zn(CH₃COO)₂ would decompose to form ZnO nanoparticles, ZnO nanowires, and Zn, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

ZrO₂, Zr
1) Dissolve Zr(CH₃CH₂COO)₄ in ethanol or isopropanol, and dip the solution into the CNTAs. When heated to 200 to 700° C., Zr(CH₃CH₂COO)₄ would decompose to form ZrO and Zr, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

Nb₂O₅, Nb
1) Dissolve ammonium niobium oxide oxalate hydrate or niobium oxalate in ethanol, and dip the solution into the CNTAs. When heated to 200 to 700° C., the solute would decompose to form Nb₂O₅ and Nb, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

Ta₂O₅, Ta
1) Dissolve Tantalum alkoxides in ethanol, and dip the solution into the CNTAs. When heated to 200 to 700° C., Tantalum alkoxides would decompose to form Ta₂O₅ and Ta, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

MoO₃, Mo
1) Dissolve Mo(CH₃COO) ₂ in ethanol, and dip the solution into the CNTAs. When heated to 200 to 700° C., Mo(CH₃COO)₂ would decompose to form MoO₃ and Mo, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

RuO₂, Ru
1) Dissolve Ru(CH₃COO)₂ in ethanol, and dip the solution into the CNTAs. When heated to 200 to 700° C., Ru(CH₃COO) ₂ would decompose to form RuO₂ and Ru, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

Ag₂O, Ag
1) Dissolve Ag(CH₃COO) in ethanol, and dip the solution into the CNTAs. When heated to 200 to 700° C., Ag(CH₃COO) would decompose to form Ag and Ag₂O, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

SnO₂, SnO, Sn
1) Dissolve SnCl₄ in ethanol, and dip the solution into the CNTAs. When heated to 150 to 700° C., Ag(CH₃COO) would decompose to form SnO₂, SnO, and Sn, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

Sb₂O₃, Sb
1) Dissolve Sb(CH₃COO)₃ in ethanol, and dip the solution into the CNTAs. When heated to 200 to 700° C., Sb(CH₃COO)₃ would decompose to form Sb₂O₃ and Sb, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

CeO₂
1) Dissolve Ce(CH₃COO)₃ in ethanol, and dip the solution into the CNTAs. When heated to 200 to 700° C., Ce(CH₃COO)₃ would decompose to form CeO₂, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

La₂O₂CO₃, La₂O₃
1) Dissolve La(CH₃COO)₃ in ethanol, and dip the solution into the CNTAs. When heated to 150 to 700° C., La(CH₃COO)₃ would decompose to form La₂O₂CO₃ and La₂O₃, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

PdO, Pd
1) Dissolve PdCl₂ in ethanol, and dip the solution into the CNTAs. When heated to 150 to 700° C., PdCl₂ would decompose to form PdO and Pd, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

Y₂O₃
1) Dissolve Y(CH₃COO)₃ in ethanol, and dip the solution into the CNTAs. When heated to 200 to 700° C., Y(CH₃COO)₃ would decompose to form Y₂O₃, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

In₂O₃, Tin-doped indium oxide (ITO), In
1) Dissolve In(CH₃COO)₃ in ethanol, and dip the solution into the CNTAs. When heated to 200 to 700° C., In(CH₃COO)₃ would decompose to form In₂O₃ and In, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))
2) Dissolve In(CH₃COO)₃ and SnCl₄ in ethanol, and dip the solution into the CNTAs. When heated to 200 to 700° C., the solutes would decompose to form ITO, depending on the heating temperature and environment (inert gases (e.g., N₂, Ar), reducing gases (e.g., H₂, Ar/H₂, N₂/H₂) and oxidation gases (e.g., air, O₂, Ar/O₂, N₂/O₂))

Au
1) Dissolve the diblock copolymer [polystyrene₈₁₀₀-block-poly(2-vinylpyridine)₁₄₂₀₀] in toluene. Add HAuCl₄.3H₂O into the solution to form gold particle precursors. Dip the precursors into the CNTAs. When heated to 200 to 700° C., the solutes would decompose to form Au.

The non-aqueous solvent is not limited to ethanol. The metallic salts that used as precursors are not limited to metal acetates.

After dip-casting, the electroplating method in aqueous or non-aqueous electrolytes can be used to deposit more forms and morphologies of oxides or metallic elements into CNTAs, for example, MnO₂, Ni/Cu alloys, etc.

The disclosed methods are particularly suitable for use with ultra-long carbon nanotubes. In this section, a method of fabricating ultra-long carbon nanotube arrays (CNTA) on an oxide catalyst layer is disclosed. In one embodiment, the oxide catalyst is a metal oxide. Any typical carbon nanotube catalyst's oxide can be used. Generally, these will be a pure oxide of a group VIII element, including Fe, Co, Ni, or the other group VIII elements of Ru, Rh, Pd, Os, Ir, or Pt. Fe oxide is a preferred catalyst due to its high activity to grow CNTAs. Although results are not provided for other than iron oxide, the utility of other group VIII oxides may be soundly predicted from their similar properties to iron oxide.

The oxide catalyst may be deposited on a substrate used as a support. The substrate used to support a catalyst layer is not critical. It could be a single crystal silicon wafer (not necessary to be oxidized), quartz, ceramics, glass, and also metals and alloys. Depending on the oxide used as the oxide catalyst, and the nature of the substrate, an intermediate layer may be provided to prevent diffusion of the oxide catalyst into the substrate. Thus, in the case of iron oxide used as the oxide catalyst, an alumina sub-layer on top of the substrate may be important to grow millimeter-long CNTA, although its thickness is not critical. Normally, it could be from around 5 nm to 40 nm, with 10 to 20 nm being preferred. An alternative for the sub-layer is aluminum metallic layer. (See FIG. 1). An oxide catalyst layer may be deposited on the top of the intermediate layer or substrate. The oxide catalyst layer may have a thickness from 0.5 nm to 10 nm, with 1 to 2 nm being preferred for the example of iron oxide.

All kinds of thin film deposition methods (physical and chemical deposition methods) can be used to deposit the oxide catalyst layer. By ways of example and not limitation, sputtering, electron-beam deposition, electro-deposition, electroless deposition, thermal evaporation, and a variety of chemical vapor deposition methods. An example of depositing a Fe oxide catalyst layer is using magnetron sputtering at room temperature under Ar and O₂ flows. The Ar/O₂ flow rate ratio is from 100:1 to 10:1, with between 40:1 and 30:1 being preferred. Direct deposition of a pure oxide catalyst layer, on one hand, saves the complicated steps of depositing composite catalyst layers and being treated by oxidizing and reducing consecutively; on the other hand, it extends the lengthening time of CNTA growth, which improves the controllability and reproducibility of CNTA growth.

For the deposition of 1 to 2 nm Fe catalyst films, it is inevitable to form partially oxidized Fe films if oxygen is present, rather than pure metallic Fe film. Direct deposition of a pure Fe oxide catalyst film significantly affects the stability of the growth process of ultra-long CNTAs, which is superior to the deposited metallic Fe film even being partially oxidized. This was found by an accident, because of the leaking of Ar gas feeding line during sputtering in our lab.

A Fe layer could be formed followed by oxidation of the Fe layer in situ, but this process is hard to control for oxidizing a 1-3 nm deposited Fe layer. For one thing, the catalyst layer may be broken into particles before the total layer is oxidized. This is why Shanov et al. (US 2008/0095695 A1) deposited a composite film and then oxidized the composite film at an intermediate temperature (the second element Gd or La was used to inhibit the diffusion of Fe atoms during oxidation and reduction steps). For another, it's difficult to control the oxygen concentration in the film within a fine range under this circumstance. In our case, oxygen is intentionally added with controlled levels.

The oxide catalyst layer may be broken up into particles by heating before nanotubes are grown on the oxide catalyst layer. A substrate has an intermediate layer such as for example alumina, and oxide catalyst particles on the intermediate layer. Carbon nanotubes may grow from the oxide catalyst particles.

The CNTA is grown on the oxide catalyst layer under conditions promoting CNT growth. CNT growth is dependent on temperature, concentration of oxidizing molecules and carbon availability. One embodiment of the method comprises depositing an oxide catalyst layer on the substrate, heating the catalyst layer at certain rates to the target temperatures, adding oxidation molecules for the pretreatment of the oxide catalyst layer, and growing the array on the substrate. For growing CNTs, it is desirable to pump down the CVD furnace reaction chamber to 0.1 to 1 Torr, and purge with Ar gas afterwards. The vacuum level is not critical for the present invention, but maintaining vacuum level enhances reproducibility of CNTA growth.

In another embodiment, carbon nanotube (CNT) wall number and CNTA height can be controlled simultaneously by changing concentration of oxidizing molecules, carbon precursor flow rates, and the pretreatment time for the oxide catalyst layer. Oxidizing molecules concentration, carbon precursor flow rates, and pretreatment time or the catalyst layer will change the CNT wall number in the lengthening stage. CNT wall number and CNTA height can be controlled simultaneously.

CNTA purity can also be controlled by the CNTA growth time. Without adding oxidizing molecules in the pretreatment stage, CNTA height could also be adjusted by using different growth time and pretreatment time.

In another embodiment, the lengthening time of CNTA can be substantially increased by increasing H₂ gas flow rate in the CNTA growth stage. H₂ gas flow rate is also important in the heating and pretreatment stages for precise control of particle size of the oxide catalyst. Different H₂ gas flow rates will change the optimum heating rate and pretreatment time for the catalyst layer.

An example of preparing samples by Magnetron sputtering is presented as following: two thin films were sputtered on the piranha cleaned Si wafers, 30 nm-thick Al₂O₃ buffer layer and 1 nm-thick Fe oxide catalyst film. The deposition rate was calibrated by a quartz crystal monitor under the real deposition conditions before any sputtering process. The base pressure was <1.0×10⁻⁷ mTorr. Pulsed-DC magnetron sputtering was used to deposit Al₂O₃ buffer layer at 300° C. with a frequency of 20 kHz and a reverse time of 5 μs. During the deposition, the working pressure was controlled at 5 mTorr with the gas flow rates of Ar (99.999%) and O₂ (99.999%) being 0.98 sccm and 0.14 sccm, respectively. After cooling down to the room temperature, 1 nm-Fe oxide catalyst films were then DC magnetron sputtered on top of the buffer layer at a working pressure of 4 mTorr under the flows of 19 sccm Ar gas and 1.3 sccm O₂ gas (flow rate ratio is 15:1). The power was kept at a very low value, 25 W, ensuring the uniform deposition of Fe oxide catalyst films. This small change of adding 1.3 sccm O₂ gas in the sputtering chamber substantially inhibits the breakage of the catalyst film to nanometer-size catalyst particles during heating step; and thus, stabilizes the growth process of ultra-long CNTAs.

Although the detailed structural change of the catalyst film by adding 1.3 sccm O₂ gas has not been clarified, the beneficial effects brought by this step have been clearly identified. Direct deposition of a pure oxide catalyst layer, on one hand, saves the complicated steps of depositing composite catalyst layers and being treated by oxidizing and reducing consecutively; on the other hand, saves the special setup (e.g. three-zone) of the furnace for the fast-heating step. In other words, this step allows the use of a regular tube furnace and a regular procedure to grow CNTAs. For an example, in the heating step, the heating rate used is 40° C./min from room temperature (25° C.) to one of the target temperatures (775° C.) under Ar (100 sccm) and H₂ (200-400 sccm) gas mixtures.

Furthermore, this small change of the sputtering environment, together with the adding of additional oxidizing molecules in the pretreatment step, brings out the phenomena of: 1) super-long lengthening time of ultra-long CNTA growth; 2) large diameter and controlled CNT wall number in CNTAs. This is because this step allows the catalyst film to break into fairly large catalyst particles (10-20 nm), compared with very small catalyst particles (less than 5 nm) prepared by fast-heating treatment.

If we sputter the catalyst film in pure Ar environment, the color of the sputtered layer is brown; however, if we sputter the oxide catalyst film in Ar/O₂ environment, the sputtered layer is transparent (it maintains the color of the Si wafer).

For a specific example of iron oxide catalyst grown on an alumina substrate, a specific set of process conditions may begin as follows. Heat the oxide catalyst layer to the target temperatures for CNTA growth. The target temperatures are from 600° C. to 900° C., with 750° C. to 775° C. being preferred. Heating rate is a variable in this invention and it is important for precise control of CNT growth. The oxide catalyst layer does not need a very high heating rate, which saves the special setup (e.g. three-zone) of the furnace.

In a pretreatment step for the oxide catalyst, that is, before CNT growth, add a small amount of oxidizing molecules at the target temperatures to the mixed gases of Ar and H₂. The oxidation molecules could be water, air, ethanol, oxygen-containing aromatics, and the like. These oxidizing molecules substantially extend the range of conditions that can grow CNTAs, and also increase the activity and lifetime of catalyst particles. An example of the pretreatment condition is adding water to Ar (100 sccm) and H₂ (200 sccm) gas mixtures by using 15 sccm Ar gas bubbling through a water bath at the temperature of 23° C., and pretreat the catalyst layer for 10 min. Use of oxide catalyst allows a relatively slow coarsening of particle size, allowing for slow heating and precise control of wall number.

CNTA growth is conducted by adding carbon precursors into the furnace right after the pretreatment stage. An example for carbon precursors is using C₂H₄ gas within the range of 25 to 1000 sccm flow rates. Other carbon precursors can also be employed, such as, methane, acetylene, methanol, ethanol, carbon monoxide, and ferrocene.

Multi-walled carbon nanotube (MWCNT) array growth in this invention demonstrates lengthening and thickening stages. In the lengthening stage of WACVD, CNT wall number remains constant and catalysts preserve the activity; while in the thickening stage of WACVD, MWCNTs thicken substantially and the purity deteriorates. Once oxide catalysts have been pre-treated to form relatively small size of particles (as compared with the result using metal or composites), a CNTA may be grown with constant wall number on the oxide catalyst particles formed during pretreatment. CNTA wall number may remain constant during growth. During CNTA growth, the growth rate is controlled by concentration of oxidizing molecules, carbon activity and the pretreatment time.

Single-walled CNTAs (SWCNTAs) can also be grown by the above described procedure except that Fe oxide catalyst layer needs to be directly put into the target temperatures, and pretreated and grown within the environment containing oxidizing molecules, which requires a three-zone furnace.

In an embodiment of a dip-casting process, we first attach Mn3O4 nanoparticles to CNTs. We believe that this is not a simple attachment and it may involve a reaction between Mn3O4 and Carbon atoms from CNTs. It is believed that the Mn3O4 particles were not simply glued to the surface of CNTs but embedded through CNT walls, an indication of chemical reaction. Because of the reaction of oxide particles with Carbon atoms in CNTs, we believe that other oxides may serve as the same purpose as Mn3O4 particles in unzipping CNTs.

Interestingly, the deposited Mn₃O₄ nanoparticles demonstrate superior specific capacitance and rate capacity because of their nanosize and the excellent nanostructured scaffold, millimeter-long CNTA. Moreover, the strategies of tuning the composite structure could also be used to further improve the performance of ESs, such as increase the loading of Mn₃O₄ nanoparticles, increase the size of hydrophilic channels and use different transitional metal oxides. This 3D-nanoparticle decorated hierarchical porous structure is also desired for other applications, such as hydrogen storage, gas or liquid sensors, lithium ion batteries, etc. Therefore, it is believed that the novel, nano-architectured Mn₃O₄/CNTA composite not only demonstrates strong promise for high-performance thick and compact electrochemical supercapacitors, but also substantially extends the applications of ultra-long CNTA by using it as an ideal support for active material.

An array of CNTs in one embodiment is a set of CNTs extending from a substrate. In another embodiment, an array is an ordered array. In another embodiment, an ordered array of CNTs has gaps between CNTs that extend in straight lines.

In another embodiment, annealing the CNT or CNT array may be used to form a metal compound dispersed within the CNT or CNT array. Such metal compounds formed dispersed within the CNT or CNT array may include one or more of LiOH, MgSO₄, CaCO₃, NiCO₃, or LaO₂CO₃ as disclosed in the examples above.

Immaterial modifications may be made to the embodiments described here without departing from what is covered by the claims. In the claims, the word “comprising” is used in its inclusive sense and does not exclude other elements being present. The indefinite article “a” before a claim feature does not exclude more than one of the feature being present. Each one of the individual features described here may be used in one or more embodiments and is not, by virtue only of being described here, to be construed as essential to all embodiments as defined by the claims.

TABLE I
Capacitance values for Mn₃O₄/CNTA(0.84), Mn₃O₄/CNTA(0.33)
composite electrodes and as-grown CNTA electrode derived from cyclic
voltammetry detected in 0.5M Na₂SO₄.

| | | Mn₃O₄- | | |
|---|---|---|---|---|
| | Specific | Specific | | Area- |
| | Capacitance | Capacitance^{a} | Mn₃O₄-Specific | normalized |
| | (F/g) at | (F/g) at | Capacitance^{a} | Capacitance |
| | 2 mV/s | 2 mV/s | (F/g) at 100 mV/s | (F/cm²) |
| Mn₃O₄/ | 143 | 292 | 100 | 1.70 |
| CNTA | | | | |
| (0.84) | | | | |
| Mn₃O₄/ | 89 | 299 | 181 | 0.79 |
| CNTA | | | | |
| (0.33) | | | | |
| As-grown | 1.84 | | | 0.012 |
| CNTA | | | | |

1. A method of dispersing a metal or metal oxide within a CNT or CNT array, comprising the steps of:
exposing the CNT or CNT array to a solution containing a metal compound in a non-aqueous liquid; and
removing the non-aqueous liquid from the CNT or CNT array.

2. The method of claim 1 in which exposing comprises dipping the CNT or CNT array into a solution containing a metal compound in a non-aqueous liquid.

3. The method of claim 1 in which removing the non-aqueous liquid from the CNT or CNT array comprises drying the CNT or CNT array.

4. The method of claim 1 further comprising annealing the CNT or CNT array.

5. The method of claim 4 in which in the annealing step, a metal oxide is formed dispersed within the CNT or CNT array.

6. The method of claim 5 in which the metal oxide comprises one or more of LiOx, MgOx, CaOx, TiOx, CrOx, MnOx, FeOx, CoOx, NiOx, CuOx, VOx, ZnOx, ZrOx, NbOx, TaOx, MoOx, RuOx, AgOx, SnOx, SbOx, CeOx, LaOx, PdOx, YOx, Tin-doped Indium oxide, or InOx.

7. The method of claim 4 in which in the annealing step, a metal is formed dispersed within the CNT or CNT array.

8. The method of claim 7 in which a reduction environment is used in the annealing step.

9. The method of claim 7 in which the metal comprises one or more of Li, Mg, Ca, Cr, Mn, Fe, Co, Zn, Ni, Cu, Ni/Cu alloy, V, Zr, Nb, Ta, Ti, Mo, Ru, In, Sn, Sb, Ag, Au or Pd.

10. The method of claim 1 in which exposing comprises dripping the solution containing a metal compound onto the CNT or CNT array after dipping the CNT or CNT array into the solution containing a metal compound.

11. The method claim 1 in which the metal compound comprises Mn(CH₃COO)₂.

12. The method of claim 1 in which the CNT or CNT array is produced by CCVD.

13. The method of claim 1 in which the non-aqueous solution comprises ethanol.

14. (canceled)

15. A CNT or CNT array comprising a metal or metal oxide dispersed within the CNT or CNT array.

16.-19. (canceled)

20. A method of dispersing a metal or metal oxide within a CNT, comprising the steps of:
physically contacting a metal or metal oxide precursor with a CNT; and
annealing the CNT and metal or metal oxide precursor to cause a metal or metal oxide to bind chemically with carbon atoms of the CNT.

21. The method of claim 20 in which the CNT is a random CNT and physically contacting a metal or metal oxide precursor with a CNT comprises at least one of electroplating, sputtering, chemical vapor deposition, atomic layer deposition and physical vapor deposition.

22. The method of claim 20 in which the CNT is part of a CNTA array and physically contacting a metal or metal oxide precursor with a CNT comprises:
exposing the CNTA to a solution containing a metal compound in a non-aqueous liquid; and
removing the non-aqueous liquid from the CNTA.

23. The method of claim 22 in which exposing comprises dipping the CNTA into a solution containing a metal compound in a non-aqueous liquid.

24. The method of claim 22 in which removing the non-aqueous liquid from the CNTA comprises drying the CNTA.

25.-31. (canceled)
